(19) United States
(12) Patent Application Publication
(10) Pub. No.: US 2026/0148951 A1
(43) Pub. Date: May 28, 2026

(54) SPECTRAL RANGE EXTENSION FOR LASER-SUSTAINED PLASMA LIGHT COLLECTION

(71) Applicant: KLA Corporation, Milpitas, CA (US)

(72) Inventors: Markus Mingebach, Elz (DE); Ilya Bezel, Mountain View, CA (US); Christopher Almodovar, Ann Arbor, MI (US); Deepak Kumar Batheja, Ann Arbor, MI (US); John Fielden, Los Altos, CA (US); Vahid Esfandyarpour, San Jose, CA (US); David Zimdars, Ann Arbor, MI (US)

(21) Appl. No.: 19/367,428

(22) Filed: Oct. 23, 2025

Related U.S. Application Data
(60) Provisional application No. 63/726,235, filed on Nov. 27, 2024.

(51) Int. Cl. H01J 61/10; G03F 7/00; H01J 61/02; H01J 61/16

(52) U.S. Cl. CPC H01J 61/103; H01J 61/025; H01J 61/16; G03F 7/70033; H01J 2893/0063

(57) ABSTRACT

A laser-sustained broadband light source is disclosed. The light source may include a gas containment structure, a pump laser source, and a light collector element. The gas containment structure may include a body formed from an optically transparent material, such as fused silica, and one or more windows transmissive to vacuum ultraviolet (VUV) light. The one or more windows may be bonded to one or more extension portions, thereby ensuring a sealed internal gas volume and avoiding exposure of metal components to destructive VUV radiation. The pump laser source may be configured to direct the pump beam into the gas containment structure to sustain a plasma, emitting broadband light through the one or more windows. Optional retroreflectors may be included to enhance light collection efficiency. The light source configuration extends the spectral range into the VUV and/or infrared regions, improves manufacturability, and enhances plasma stability.

### CROSS-REFERENCE TO RELATED APPLICATION

The present application claims priority to U.S. Provisional Application Ser. No. 63/726,235, filed Nov. 27, 2024, which is incorporated herein by reference in their entirety.

### TECHNICAL FIELD

The present disclosure generally relates to broadband light sources, and,

more particularly, to laser-sustained plasma (LSP) light sources for extending the spectral range in semiconductor metrology and inspection systems.

### BACKGROUND

Laser-sustained plasma (LSP) light sources are widely used in broadband inspection and metrology tools for semiconductor manufacturing. Generally, near-infrared continuous-wave pump laser light is focused into a high-pressure gas medium—such as xenon, argon, krypton, or mixtures thereof—contained within an optically transparent vessel. The pump laser ignites and sustains a plasma in the vessel, and emission from the plasma is collected through the vessel's transparent components and directed into optical inspection or imaging systems. LSP light sources are widely used in broadband inspection and metrology tools for semiconductor manufacturing.

There have been various versions of such sources developed. Many existing LSP sources are optimized for the visible and ultraviolet spectral regions and rely on fused silica or quartz vessels that transmit light only down to about 170 nm. When vacuum ultraviolet wavelengths below this cutoff are required, windows (e.g., magnesium fluoride, calcium fluoride, or lithium fluoride) are incorporated into the vessel. In some cases, conventional approaches employ metal-based pressure cells with brazed or sealed crystalline windows, but these designs introduce manufacturing complexity, multiple potential leak paths, and heightened risk of seal failure. Also, the high thermal conductivity of metal vessels creates cold spots that induce turbulent convective flow, thereby degrading plasma stability and optical output. Moreover, alternative VUV sources, such as low-pressure deuterium lamps, offer limited brightness and are unsuitable for high-throughput inspection or metrology applications.

As a result, providing a broadband light source that extends the usable spectral range into the vacuum ultraviolet and infrared regions while enhancing manufacturability, sealing reliability, and emission stability is desirable.

### SUMMARY

A laser-sustained broadband light source is disclosed. In some aspects, the light source includes a gas containment structure configured to contain a pressurized gas. In some aspects, the light source includes a pump laser source configured to generate a pump beam. In some aspects, the gas containment structure comprises a body formed from a first optically transparent material that is transmissive to the pump laser beam. In some aspects, the gas containment structure further includes one or more windows formed from a material that is transmissive to vacuum ultraviolet light. In some aspects, the gas containment structure includes one or more extension portions, with each extension portion connecting the body of the gas containment structure to a respective window. In some aspects, each window is hermetically joined to its respective extension portion to define a sealed internal gas volume. In some aspects, the light source includes one or more optical elements configured to direct the pump laser beam from the pump source through the body of the gas containment structure into the sealed internal gas volume to sustain a plasma in the gas. In some aspects, a light collector element is provided to collect broadband light emitted by the plasma through the one or more windows.

A characterization system is disclosed. In some aspects, the characterization system incorporates the laser-sustained broadband light source described above, together with a set of illumination optics for directing broadband light onto one or more samples, a set of collection optics for collecting light emanating from the one or more samples, and a detector assembly for analyzing the collected light.

A method for generating broadband light using a laser-sustained plasma source is provided. In some aspects, the method includes providing a gas containment structure comprising a body formed from a first optically transparent material and one or more extension portions, with each extension portion connecting the body to a respective window transmissive to vacuum ultraviolet light. In some aspects, each window is hermetically joined to its corresponding extension portion to define a sealed internal gas volume. In some aspects, the method includes introducing a pressurized gas into the sealed internal gas volume. In some aspects, a pump beam is generated with a pump laser source. In some aspects, the pump beam is directed through the body into the sealed internal gas volume via one or more optical elements to ignite and sustain a plasma in the pressurized gas. In some aspects, broadband light emitted by the plasma is collected through the windows using a light collector element.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The numerous advantages of the disclosure may be better understood by those skilled in the art by reference to the accompanying figures.

FIGS. 1A-1B illustrate simplified schematic views of the LSP broadband light source with extended spectral range, in accordance with one or more embodiments of the present disclosure.

FIGS. 2A-2D illustrate various arrangements of an electrodeless gas containment structure, in accordance with one or more embodiments of the present disclosure.

FIGS. 3A-3D illustrate various tube-based arrangements for the electrodeless gas containment structure, in accordance with one or more embodiments of the present disclosure.

FIGS. 4A-4D illustrate various fill port and valve arrangements integrated with a sleeve of the gas containment structure, in accordance with one or more embodiments of the present disclosure.

FIGS. 5A-5C illustrate various fill port arranges formed in the bulb of the gas containment structure, in accordance with one or more embodiments of the present disclosure.

FIGS. 6A-6E illustrate various window sealing arrangements, in accordance with one or more embodiments of the present disclosure.

FIG. 7A-7F illustrate various arrangements for joining one or more sleeves with one or more extension portions, in accordance with one or more embodiments of the present disclosure

FIG. 8 illustrates a schematic view of an optical characterization system incorporating the LSP broadband light source for metrology and inspection applications, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to a laser-sustained (LSP) broadband source with extended usable spectral range with improved manufacturability, sealing reliability, and emission stability. Embodiments of the present disclosure address limitations of conventional light sources by enabling efficient transmission of VUV and infrared wavelengths through the use of a specialized gas containment structure. In particular, the light source incorporates a body formed from an optically transparent material, such as fused silica, and one or more windows, such as, but not limited to, magnesium fluoride (MgF₂), calcium fluoride (CaF₂), lithium fluoride (LiF), sapphire, or SBO, that are hermetically joined to the body via extension portions. This configuration allows for stable plasma generation within a sealed internal gas volume, while facilitating the extraction of broadband light through the windows.

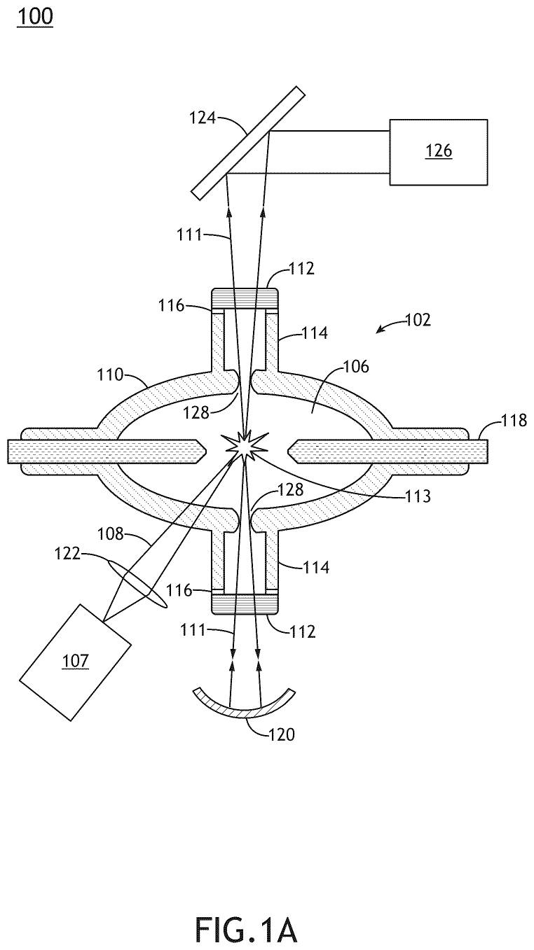

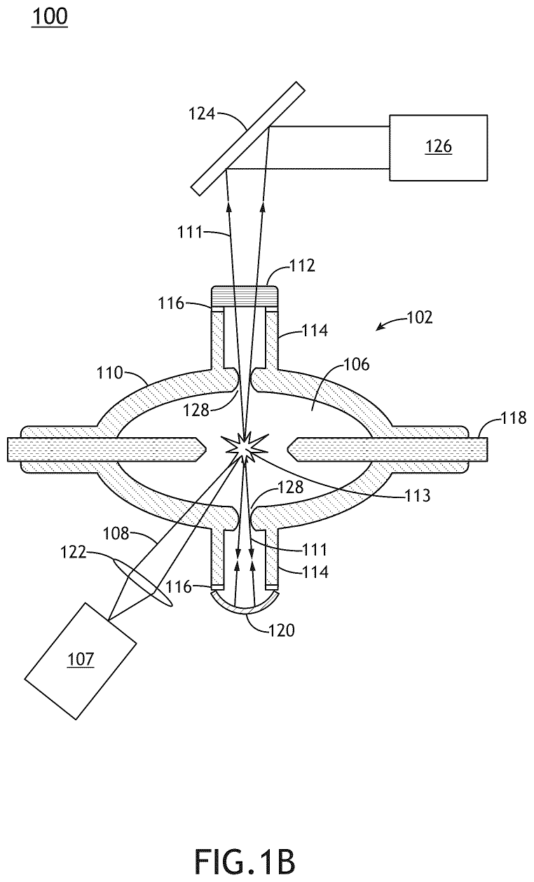

FIG. 1A illustrates a simplified schematic view of an LSP broadband light source 100, in accordance with one or more embodiments of the present disclosure. In embodiments, the light source 100 includes a gas containment structure 102 configured to contain a pressurized gas 106. In embodiments, the light source 100 includes one or more pump laser sources 107 configured to generate a pump beam 108. For example, the one or more pump laser sources 107 may include, but are not limited to, one or more continuous-wave (CW) lasers (e.g., IR CW laser). In embodiments, the gas containment structure 102 includes a lamp body 110 formed from a first optically transparent material transmissive to the pump beam 108. In embodiments, the gas containment structure 102 includes one or more windows 112 formed from a material transmissive to a selected spectral range of broadband light 111 emitted by the plasma 113. For example, the one or more windows 112 may be formed from material transmissive to vacuum ultraviolet light. By way of another example, the one or more windows 112 may be formed from material transmissive to infrared light. In embodiments, the gas containment structure 102 includes one or more extension portions 114. For example, each of the one or more extension portions 114 connects the body 110 of the gas containment structure 102 with a window 112. The inclusion of one or more windows 112 made from VUV-transparent materials, such as magnesium fluoride (MgF₂) or calcium fluoride (CaF₂), allows the transmission of vacuum ultraviolet (VUV) wavelengths that are otherwise blocked by traditional bulb materials, such as fused silica. This design extends the usable spectral range of the light source 100 into the VUV region, rendering the light source 100 appropriate for advanced semiconductor metrology and inspection applications. In embodiments, the one or more windows 112 are hermetically joined by one or more seals 116 to the one or more extension portions 114 to define a sealed internal gas volume. The hermetic joining of windows 112 to the extension portions 114 ensures a sealed internal gas volume, preventing gas leakage and maintaining the high-pressure environment required for plasma generation. This improves the reliability and longevity of the light source while simplifying manufacturing compared to metal-based pressure cells. The use of extension portions 114 to connect body 110 of the gas containment structure 102 with windows 112 also provides a modular design that facilitates the integration of different window materials. This modularity allows for customization of the spectral range based on specific application requirements.

In embodiments, the gas containment structure 102 includes one or more constriction holes 128. The constriction holes 128 may be formed in the wall of body 110 of the gas containment structure 102 and serve to connect the internal portion of the gas containment structure 102 with the extension portions 114, while regulating the flow of hot gas between the main plasma region and the extension portions 114. This configuration serves to maintain stable thermal and convective conditions within the gas containment structure 102 by the effective isolation of the plasma region while allowing necessary gas exchange with the extension portions 114. By controlling the movement of gas, the constriction holes 128 reduce turbulence and prevent unwanted mixing, which supports stable plasma operation and consistent broadband light emission.

In embodiments, the LSP broadband source 100 includes electrodes 118. Electrodes 118 are provided within the gas containment structure 102 to assist in the ignition and maintenance of the plasma. In embodiments, a pair of electrodes 118 is positioned inside the body 110 of the gas containment structure 102 (e.g., positioned at opposite ends of the gas containment structure 102), to establish an electrical discharge across the pressurized gas. This discharge initiates the plasma, which is then sustained by the pump laser beam. Electrodes 118 may be fabricated from materials compatible with the operating environment, such as tungsten or other refractory metals, to withstand high temperatures and corrosive conditions within the plasma region.

In embodiments, the LSP broadband light source includes a retroreflecting mirror 120. The retroreflecting mirror 120, or retroreflector, is configured to enhance the collection and utilization of broadband light 111 emitted by the plasma 113 within the gas containment structure 102. In embodiments, the retroreflecting mirror 120 is positioned adjacent to one of the windows 112 that is transparent to vacuum ultraviolet (VUV) light. In alternative and/or additional embodiments, as shown in FIG. 1B, the retroreflecting mirror 120 may be attached directed to the gas containment structure 102. For example, the retroreflecting mirror 120 may be attached to an extension portion 114 in place of a window 112. The retroreflecting mirror 120 may be formed as an elliptical or spherical mirror, or may comprise other suitable reflective geometries, and is arranged to redirect broadband light 111 that exits the plasma 113 through the window 112 back into the plasma region. By reflecting light back into the plasma, the retroreflecting mirror 120 increases the effective optical power and improves the overall light collection efficiency of the source 100. This configuration is particularly advantageous for maximizing the usable output of VUV and other broadband wavelengths, supporting high-throughput metrology and inspection applications. The retroreflecting mirror 120 may be fabricated from materials compatible with the operating environment and spectral range and may be mounted either inside or outside the gas containment structure 102.

In embodiments, the light source 100 includes one or more optical elements 122 configured to direct the pump laser beam 108 from the pump source 107 into the body 110 of the gas containment structure 102 into the sealed internal gas volume to sustain a plasma 113 in the gas 106. The one or more optical elements 122 may include any type and number of optical elements including, but not limited to, one or more lenses, one or more mirrors, one or more beamsplitters, or one or more filters.

In embodiments, the light source 100 includes a light collector element 124 configured to collect broadband light 111 emitted by the plasma 113 through the one or more windows 112. In embodiments, the light collector element 124 may direct and/or focus the broadband light 111 to one or more downstream applications 126. The light collector element 124 may include any type and number of light collection elements including, but not limited to, one or more lenses or one or more mirrors. In embodiments, the light collector element may include a reflector assembly such as, but not limited to, an elliptical reflector or a spherical reflector. The one or more downstream applications 126 may include inspection, metrology, and/or other imaging systems.

The body 110 of the gas containment structure 102 may be formed from any suitable material that is transparent to the pump laser beam. For example, the body 110 of the gas containment structure 102 may be formed from, but is not limited to, fused silica, sapphire, strontium tetraborate (SrB₄O₇), or SBO, or other suitable glass compositions. The one or more windows 112 may be formed from materials that transmit the specific wavelengths of light to be collected, such as VUV light. For example, the one or more windows 112 may be formed from, but are not limited to, magnesium fluoride (MgF₂), calcium fluoride (CaF₂), lithium fluoride (LiF), sapphire, or SBO. The one or more extension portions 114 may be formed from the same material as the body 110 or a different material as the body 110. For example, the body 110 and the one or more extension portions 114 may be formed by fused silica. By way of another example, the body 110 may be formed from fused silica while the one or more extension portions 114 are formed from sapphire to improve thermal and optical properties.

The gas containment structure 102 may be configured to contain any gas or gas mixture of two or more gases suitable for use in LSP broadband light production. In embodiments, the gas contained within the body 110 of the gas containment structure 102 includes, but is not limited to, xenon, argon, krypton or mixtures thereof. In some embodiments, the gas mixture may also include fluorine-containing compounds which may protect vacuum ultraviolet (VUV) transparent windows, such as magnesium fluoride or calcium fluoride, from chemical degradation.

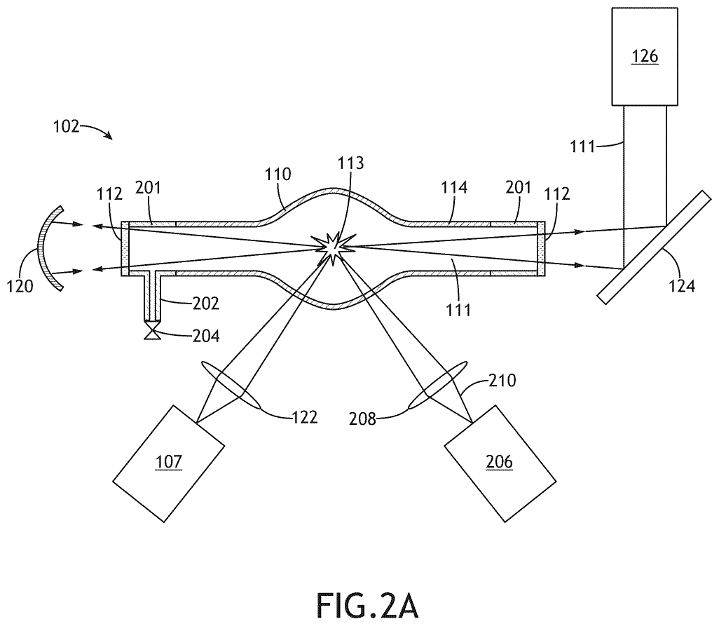

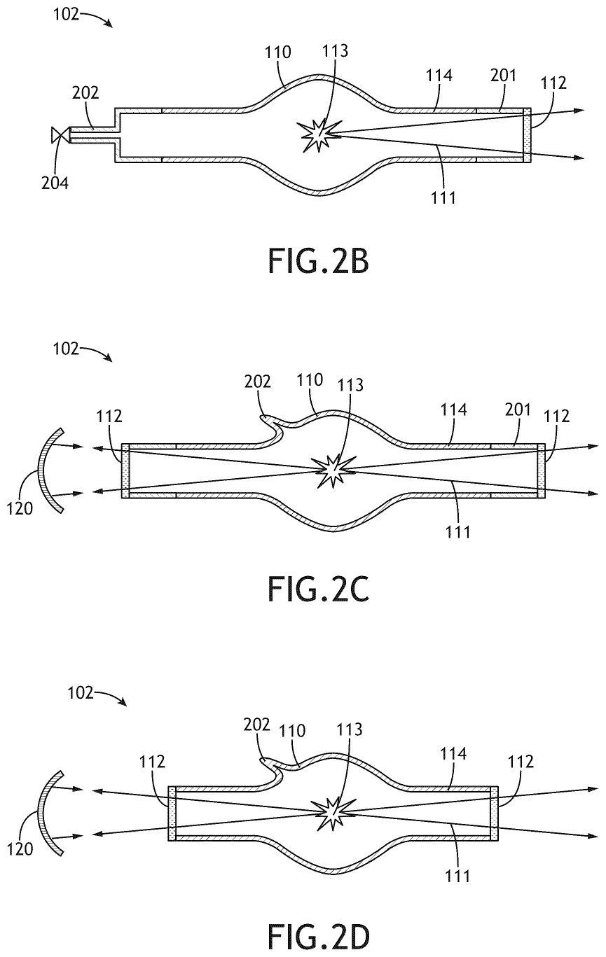

FIGS. 2A-2D illustrate various arrangements of the gas containment structure 102 with an electrodeless configuration, in accordance with one or more embodiments of the present disclosure. As previously discussed herein, in embodiments, the body 110 of the gas containment structure 102 is formed from a material transparent to the laser pump beam 108 and is configured to contain a pressurized gas for generation of plasma 113, which emits broadband light 111. In embodiments, the gas containment structure 102 includes one or more extension portions 114 (e.g., one or more extension tubes) and one or more windows constructed from material transparent to vacuum ultraviolet (VUV) light and disposed at the end of each extension portion 114. In embodiments, the gas containment structure 102 includes one or more sleeves 201 for joining the one or more windows 112 to the one or more extension portions 114. In embodiments, the gas containment structure 102 includes a fill port 202. The fill port 202 may be located on the bulb body or the sleeve 201 enabling introduction of the pressurized gas into the body 110 of the gas containment structure 102 and can be sealed using a valve or a glass-sealed port. In this embodiment, the lamp body 110 is formed with a bulb at the center of the gas containment structure 102. For example, the lamp body 110 may be formed as an oblate bulb.

In embodiments, the LSP broadband light source 100 includes a pulsed laser source 206. The pulsed laser source 206 may be used to ignite the plasma 113 within any of the electrodeless variations of the present disclosure. In these embodiments, the pulsed laser source 206, such as, but not limited to a Q-switched laser or a mode-locked laser, may deliver short, high-intensity pulses of light into the pressurized gas contained in the body 110 of the gas containment structure 102, initiating plasma formation without the need for internal electrodes. The pulsed laser source 206 and one or more optical elements 208 may be positioned to direct its beam 210 through the body 110 or window 112 of the gas containment structure. In embodiments, the pulsed laser source 206 may include dedicated optics 208 and direct pulsed laser light along a dedicated optical path to the plasma generation region different from the optical path of the pump laser source 107. In alternative and/or additional embodiments, the ignition beam from the pulsed laser source 206 and the pump beam from the pump laser source 107 may at least partially share an optical path. For example, the pulsed laser source 206 may be configured to direct laser pump illumination along a shared optical path with the primary pump source 107 using suitable optics such as a dichroic mirror or beam splitters. Once the plasma 113 is ignited by the pulsed laser source 206, the pump laser beam 108 sustains the plasma for continuous broadband light emission.

FIG. 2A illustrates an electrodeless gas containment structure 102 including two sleeves 201, in accordance with one or more embodiments of the present disclosure. In embodiments, each extension portion 114 is joined to its corresponding window 112 by a sleeve 201, which provides a hermetic seal. The one or more sleeves 201 may be formed from any suitable material including, but not limited to, a metal, an alloy, a ceramic, or a glass different from the glass of the windows 112 or the extension portion 114. Details related to the construction of the one or more sleeves 201 are discussed further herein. In this embodiment, one of the sleeves 201 includes a fill port 202. The fill port 202 is equipped with a valve 204 to maintain the sealed internal gas volume. In embodiments, a retroreflecting mirror 120 is positioned adjacent to one of the windows 112 to redirect broadband light 111 back through the plasma 113, thereby enhancing light collection efficiency.

In alternative and/or additional embodiments, as shown in FIG. 2B, the gas containment structure 102 is configured in a single window configuration. In this embodiment, the gas containment structure 102 includes a single window 112. The window 112 may be coupled to the extension portion 114 via the sleeve 201, as previously discussed herein. In embodiments, the opposite end of the body 110 of the gas containment structure 102 is closed. The closed end of the body 110 may include a modified sleeve structure configured for integrating the fill port 202 and the valve 204. In alternative and/or additional embodiments, as shown in FIG. 2C, the fill port 202 is located on the bulb portion of the body 110. In this embodiment, a fill port 202 may be a glass sealed fill port and located on the bulb portion of the body 110. In alternative and/or additional embodiments, as shown in FIG. 2D, the gas containment structure 102 is configured without electrodes and without sleeves. In this embodiment, the one or more windows 112 may be mounted directly onto the one or more extension portions 114. For example, the one or more windows 112 may be connected directly to the one or more extension portions 114 by any bonding mechanism including, but not limited to, laser welding or diffusion bonding.

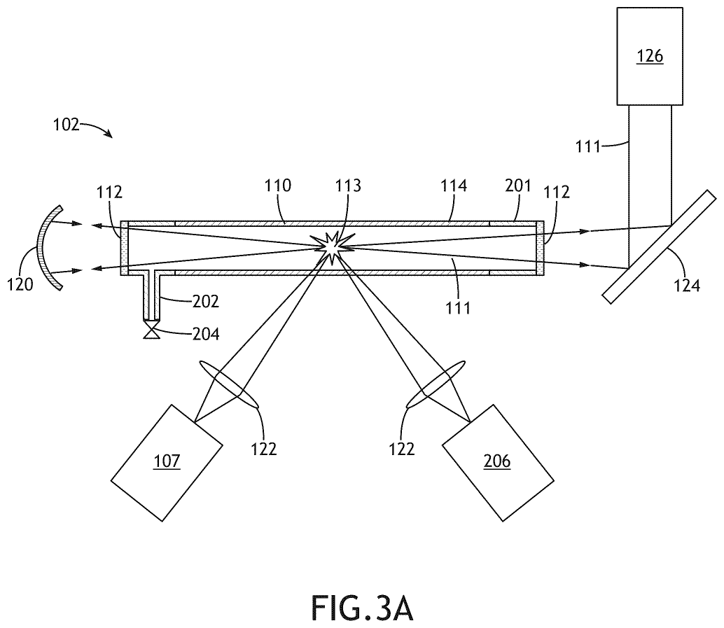

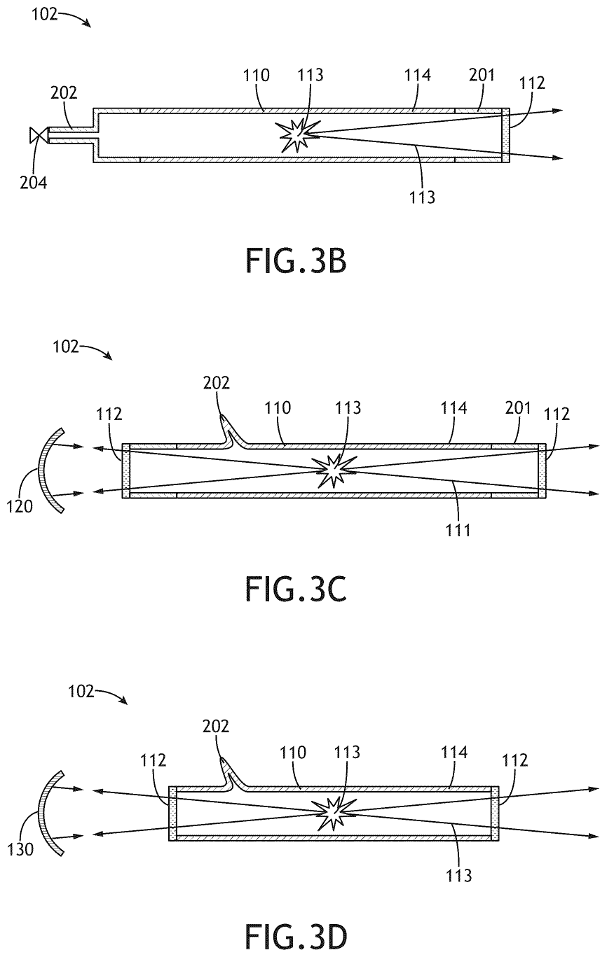

FIGS. 3A-3D illustrate various electrodeless arrangements of the gas containment structure 102 in a tube configuration, in accordance with one or more embodiments of the present disclosure. It is noted that the various embodiments of FIGS. 1A-2D should be interpreted to extend to the embodiments of FIGS. 3A-3D. In these embodiments, the body 110 of the gas containment structure 102 is shaped as a tube.

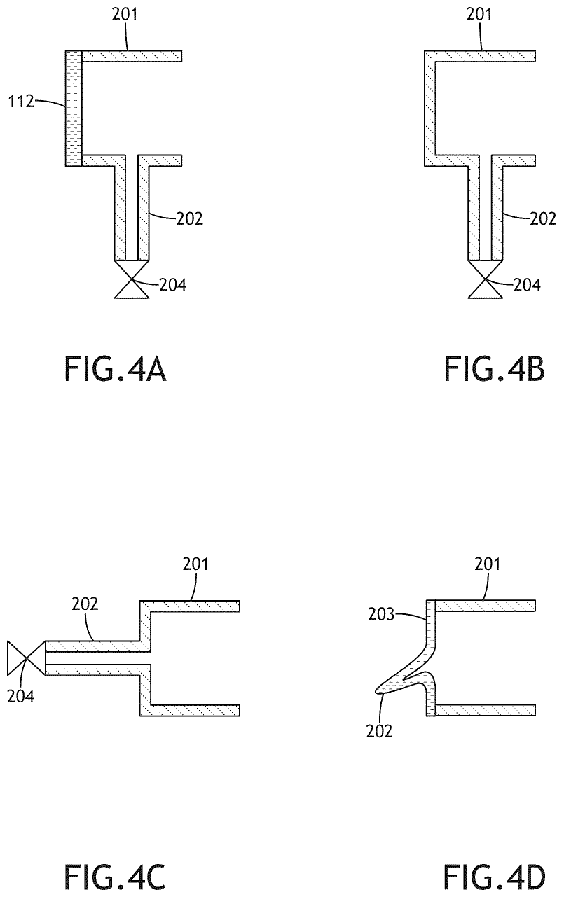

FIGS. 4A-4D illustrate various arrangements of the fill port 202 of the gas containment structure 102, in accordance with one or more embodiments of the present disclosure. In embodiments, the fill port 202 is integrated within a sleeve 201. For example, as shown in FIG. 4A, the fill port 202 and valve 204 may be integrated with the sleeve 201 securing a window 112. By way of another example, as shown in FIG. 4B, the fill port 202 and valve 204 may be integrated with a closed sleeve which terminates at an end portion of the gas containment structure. By way of another example, as shown in FIG. 4C, the fill port 202 and valve 204 is integrated with the sleeve 201 at an end portion of the sleeve 201. By way of another example, as shown in FIG. 4D, the fill port 202 may be a glass sealed fill port 202 formed in a window 203 secured by the sleeve 201.

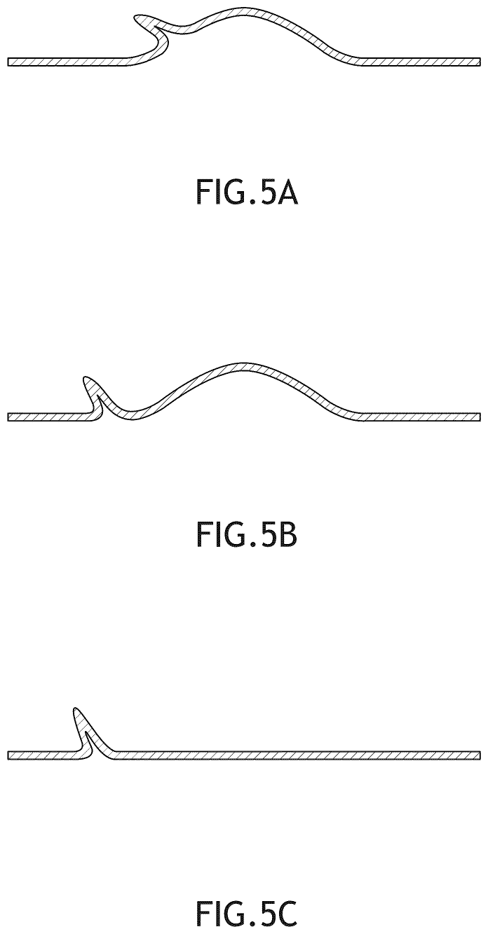

FIGS. 5A-5C illustrate various bulb-based arrangements for the fill port 202 of the gas containment structure 102, in accordance with one or more embodiments of the present disclosure. For example, as shown in FIG. 5A, the fill port 202 may be located on a bulb port of the gas containment structure 102 and sealed via a glass-sealed port. By way of another example, as shown in FIG. 5B, the fill port 202 may be located along a tubular portion of the gas containment structure 102. For instance, the fill port 202 may be formed on an extension portion of the gas containment structure 102. By way of another example, the fill port 202 may be formed on a tube-shaped bulb-less body of the gas containment structure 102.

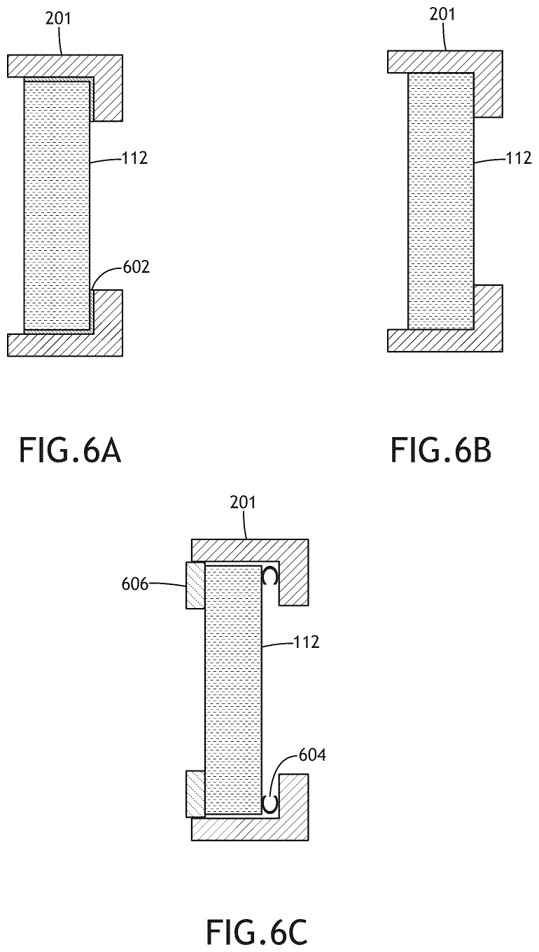

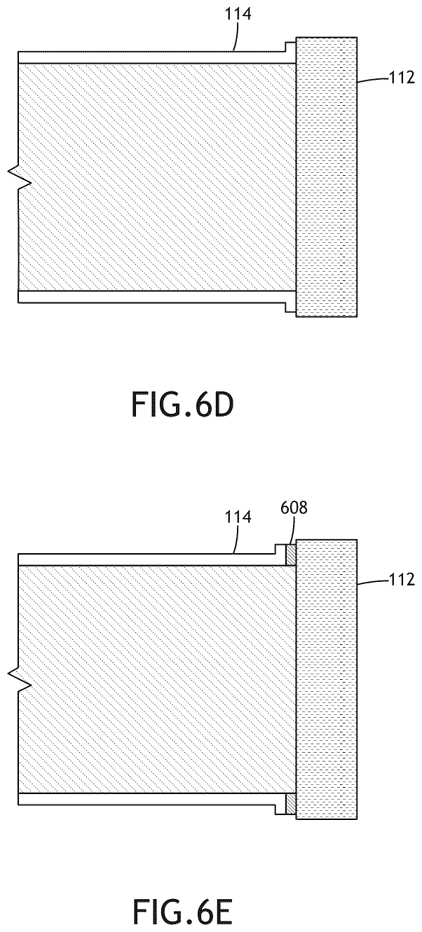

FIGS. 6A-6E illustrate various window sealing arrangements, in accordance with one or more embodiments of the present disclosure. In embodiments, the one or more windows 112 are bonded and hermetically sealed to the gas containment structure 102 using the one or more sleeves 201 or through directly bonding. It is noted that the end portion of the one or more sleeves 201 operates as a bearing surface to support the one or more windows 112 against positive interior pressure of the gas containment structure 102. In embodiments, as shown in FIG. 6A, an interlayer material 602 is used to bond the window 112 to the sleeve 201. The interlayer material 602 may include, but is not limited to, a brazing filler material, glass frit, or metal interlayer. The interlayer material may be selected to minimize stress in the joint. For example, the composition of glass frit materials may be tailored to achieve a desirable coefficient of thermal expansion. Bonding between the interlayer 602 and the sleeve 201 or the interlayer 602 and the window 112 may be achieved by conventional bulk heating (e.g., vacuum oven) or localized heating (e.g., laser welding or ultrasonic torsional welding). Moreover, multiple interlayers of different materials may be used to bond the window 112 to the sleeve 201. For example, multiple different fused silica glasses may be used in a series of interlayers to control the transition of thermal expansion coefficient from the sleeve 201 to the window 112. In embodiments, as shown in FIG. 6B, window 112 is directly bonded to sleeve 201. For example, the direct bonding of window 112 to the sleeve 201 may be achieved, but is not limited to, by fusion welding techniques, such as laser welding, or diffusion bonding techniques. In embodiments, as shown in FIG. 6C, one or more mechanical elements are configured to join window 112 and the sleeve 201. For example, the one or more mechanical elements include a compressive mechanical seal 604 and a retaining ring 606. For example, the sealing material (e.g., elastomer, metal seal, etc.) of the compressive mechanical seal 604 may be compressed between the window and the sleeve and the retaining ring 606 is fixed in place to maintain the compressive force to secure the window 112. In embodiments, as shown in FIG. 6D, window 112 is directly bonded to the extension portion 114. For example, window 112 may be directly bonded to the extension portion 114 using a direct bonding technique, such as, but not limited to, laser welding or diffusion bonding. In embodiments, as shown in FIG. 6E, window 112 is bonded to the extension portion 114 using one or more interlayers of materials. For example, window 112 may be bonded to the extension portion 114 using an interlayer material, such as, but not limited to, a glass frit. Moreover, multiple interlayers of different materials may be used to bond the extension portion 114 to the window 112. For example, multiple different fused silica glasses may be used in a series of interlayers to control the transition of thermal expansion coefficient from the window 112 to the extension portion 114.

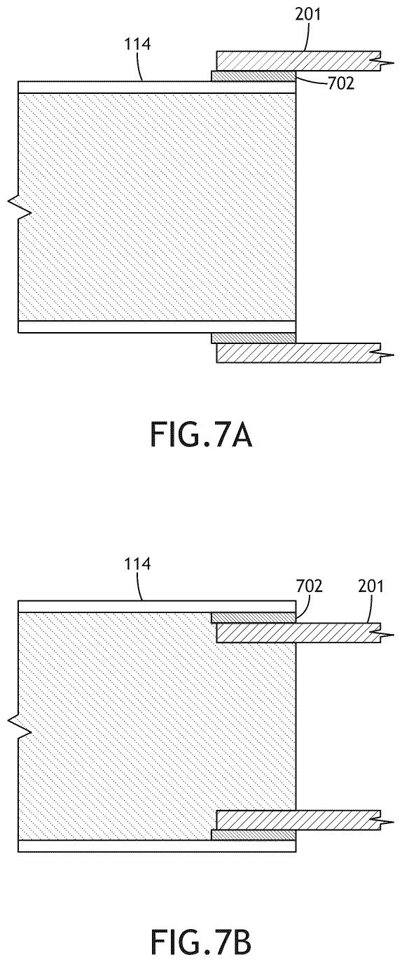

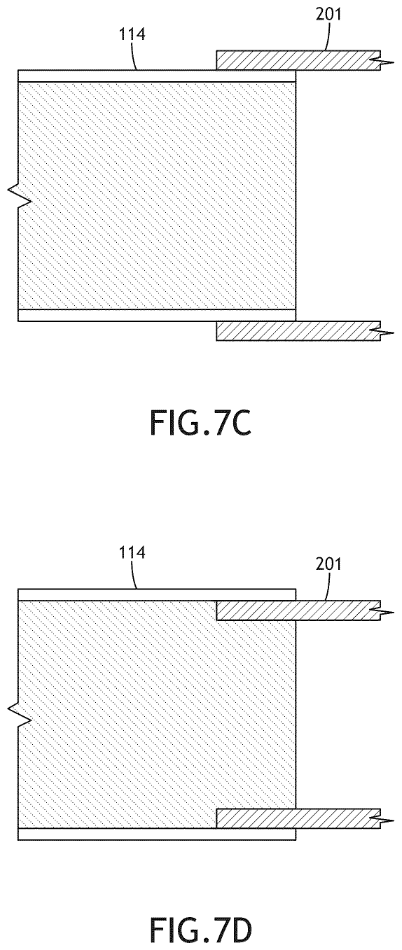

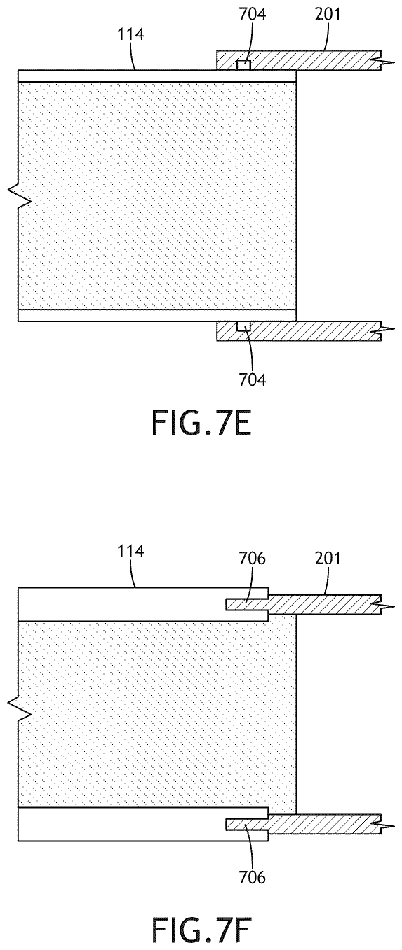

FIG. 7A-7H illustrate various arrangements for joining one or more sleeves 201 with the one or more extension portions 114 to establish a hermetic seal, in accordance with one or more embodiments of the present disclosure. In embodiments, as shown in FIGS. 7A and 7B, the one or more sleeves 201 may be joined with the one or more extension portions 114 using one or more interlayers of material 702 such as, but not limited to, a brazing filler, glass frit, or metal interlayer and a suitable bonding process. The sleeve 201 may be joined via one or more interlayers of material 702 on the outside of the extension portion, as shown in FIG. 7A, or the inside of the extension portion, as shown in FIG. 7B. In embodiments, as shown in FIGS. 7C and 7D, the one or more sleeves 201 may be joined with the one or more extension portions 114 via a direct bonding process. For example, the one or more sleeves 201 may be joined with the one or more extension portions 114 via laser welding or diffusion bonding. The sleeve 201 may be directly bonded on the outside of the extension portion, as shown in FIG. 7C, or the inside of the extension portion, as shown in FIG. 7D. In embodiments, as shown in FIGS. 7E and 7F, the one or more sleeves 201 may be joined with the one or more extension portions 114 via one or more mechanical elements. For example, the one or more sleeves 201 may be joined with the one or more extension portions 114 via one or more grooves 704. For instance, as shown in FIG. 7E, a groove 704 in the one or more sleeves 201 may couple with a corresponding protrusion/ridge of the one or more extension portions 114. In another instance, as shown in FIG. 7F, the one or more extension portions 114 may include a groove 706 which is configured to receive an end portion of the sleeve 201 to secure the sleeve 201 to the extension portion 114. It is noted that the grooves or grooved features may be employed to enhance the bonding surface area of the sleeve-extension tube joint.

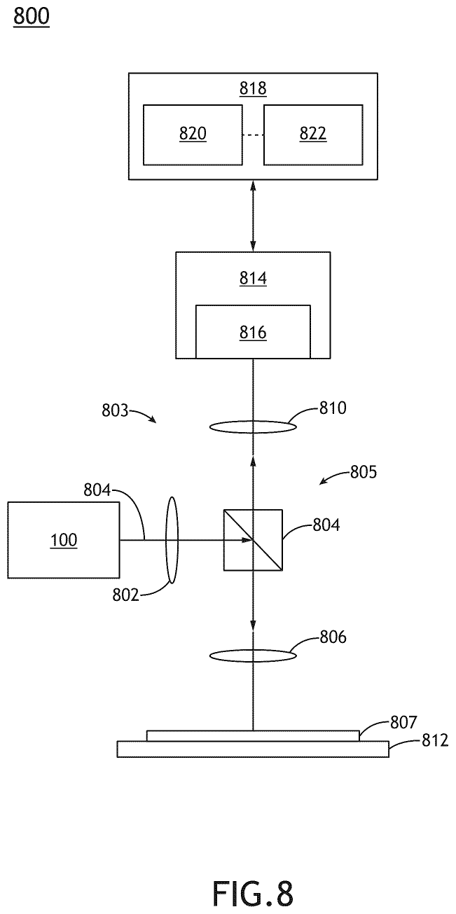

FIG. 8 illustrates a simplified schematic view of an optical characterization system 800 incorporating the compact LSP broadband light source, in accordance with one or more alternative and/or additional embodiments. In embodiments, system 800 includes the LSP light source 100, an illumination arm 803, a collection arm 805, a detector assembly 814, and a controller 818 including one or more processors 820 and memory 822.

It is noted herein that system 800 may comprise any imaging, inspection, metrology, lithography, or other characterization system known in the art. In this regard, system 800 may be configured to perform inspection, optical metrology, lithography, and/or any form of imaging on a sample 807. It is noted that the system 800 may be configured in any optical configuration known in the art including, but not limited to, a dark-field configuration, a bright-field orientation, and the like. The system 800 may be configured as any type of inspection or metrology tool known in the art and optical arrangement depicted in FIG. 8 should not be interpreted as a limitation on the scope of the present disclosure.

Sample 807 may include any sample known in the art including, but not limited to, a wafer, a reticle, a photomask, a flat panel display, and the like. It is noted that system 800 may incorporate one or more of the various embodiments of the LSP light source 100 described throughout the present disclosure.

In embodiments, sample 807 is disposed on a stage assembly 812 to facilitate movement of sample 807. Stage assembly 812 may include any stage assembly 812 known in the art including, but not limited to, an X-Y stage, an R-θ stage, and the like. In embodiments, stage assembly 812 adjusts the position of sample 807 during inspection or imaging to maintain focus on sample 807.

In embodiments, the illumination arm 803 is configured to direct broadband light 111 from the broadband LSP light source 100 to the sample 807. The illumination arm 803 may include any number and type of optical components known in the art. In embodiments, the illumination arm 803 includes one or more optical elements 802, a beam splitter 804, and an objective lens 806. In this regard, illumination arm 803 may be configured to focus broadband light 111 from the broadband LSP light source 100 onto the surface of the sample 807. The one or more optical elements 802 may include any optical element or combination of optical elements known in the art including, but not limited to, one or more mirrors, one or more lenses, one or more polarizers, one or more gratings, one or more filters, one or more beam splitters, and the like. It is noted herein that the collection location may include, but is not limited to, one or more of the optical elements 802, a beam splitter 804, or an objective lens 806.

In embodiments, system 800 includes a collection arm 805 including a set of collection optics configured to collect light emanating from the one or more samples. For example, the set of collection optics may collect light reflected, scattered, diffracted, and/or emitted from sample 807. In embodiments, collection arm 805 may direct and/or focus the light from the sample 807 to a sensor 816 of a detector assembly 814. It is noted that sensor 816 and detector assembly 814 may include any sensor and detector assembly known in the art. The sensor 816 may include, but is not limited to, a charge-coupled device (CCD) sensor or a Time Delay Integration Charge-Coupled Device (TDI-CCD) sensor. Further, sensor 816 may include, but is not limited to, a line sensor or an electron-bombarded line sensor.

In embodiments, detector assembly 814 is communicatively coupled to a controller 818 including one or more processors 820 and memory 822. For example, the one or more processors 820 may be communicatively coupled to memory 822, wherein the one or more processors 820 are configured to execute a set of program instructions stored on memory 822. In embodiments, the one or more processors 820 are configured to analyze the output of detector assembly 814. In embodiments, the set of program instructions are configured to cause the one or more processors 820 to analyze one or more characteristics of sample 807. In embodiments, the set of program instructions are configured to cause the one or more processors 820 to modify one or more characteristics of system 800. For example, the one or more processors 820 may be configured to adjust the objective lens 808 or one or more optical elements 802 in order to focus broadband light 111 from broadband LSP light source 100 onto the surface of the sample 807.

Additional details of various embodiments of optical characterization system 800 are described in U.S. Pat. No. 7,957,066B2, entitled “Split Field Inspection System Using Small Catadioptric Objectives,” issued on Jun. 7, 2011; U.S. Published Patent Application 2007/0002465, entitled “Beam Delivery System for Laser Dark-Field Illumination in a Catadioptric Optical System,” published on Jan. 4, 2007; U.S. Pat. No. 5,999,310, entitled “Ultra-broadband UV Microscope Imaging System with Wide Range Zoom Capability,” issued on Dec. 7, 1999; U.S. Pat. No. 7,525,649 entitled “Surface Inspection System Using Laser Line Illumination with Two Dimensional Imaging,” issued on Apr. 28, 2009; U.S. Published Patent Application 2013/0114085, entitled “Dynamically Adjustable Semiconductor Metrology System,” by Wang et al. and published on May 9, 2013; U.S. Pat. No. 5,608,526, entitled “Focused Beam Spectroscopic Ellipsometry Method and System, by Piwonka-Corle et al., issued on Mar. 4, 1997; and U.S. Pat. No. 6,297,880, entitled “Apparatus for Analyzing Multi-Layer Thin Film Stacks on Semiconductors,” by Rosencwaig et al., issued on Oct. 2, 2001, which are each incorporated herein by reference in their entirety.

The one or more processors 820 of the present disclosure may include any one or more processing elements known in the art. In this sense, the one or more processors 820 may include any microprocessor-type device configured to execute software algorithms and/or instructions. In embodiments, the one or more processors 820 may consist of a desktop computer, mainframe computer system, workstation, image computer, parallel processor, or other computer system (e.g., networked computer) configured to execute a program configured to operate the system 800 and/or broadband LSP light source 100, as described throughout the present disclosure. It should be recognized that the steps described throughout the present disclosure may be carried out by a single computer system or, alternatively, multiple computer systems. In general, the term “processor” may be broadly defined to encompass any device having one or more processing elements, which execute program instructions from a non-transitory memory medium 822. Moreover, different subsystems of the various systems disclosed may include processor or logic elements suitable for carrying out at least a portion of the steps described throughout the present disclosure.

The memory medium 822 may include any storage medium known in the art suitable for storing program instructions executable by the associated one or more processors 820. For example, the memory medium 822 may include a non-transitory memory medium. For instance, the memory medium 822 may include, but is not limited to, a read-only memory, a random-access memory, a magnetic or optical memory device, a magnetic tape, a solid-state drive, and the like. In another embodiment, the memory 822 is configured to store one or more results and/or outputs of the various steps described herein. In another embodiment, memory medium 822 maintains program instructions for causing the one or more processors 820 to carry out the various steps described through the present disclosure.

One skilled in the art will recognize that the herein described components, operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. A laser-sustained broadband light source comprising:
a gas containment structure configured to contain a pressurized gas;
one or more pump laser sources configured to generate a pump beam, wherein the gas containment structure comprises:
a body formed from a first optically transparent material transmissive to a pump laser beam;
one or more windows formed from a material transmissive to a selected spectral range; and
one or more extension portions, wherein a respective extension portion connects the body of the gas containment structure with a respective window, wherein the respective window is hermetically joined to the respective extension portion to define a sealed internal gas volume;
one or more optical elements configured to direct a pump laser beam from the one or more pump laser sources through the body of the gas containment structure into the sealed internal gas volume to sustain a plasma in the pressurized gas; and
a light collector element configured to collect broadband light emitted by the plasma through the one or more windows.

2. The laser-sustained broadband light source of claim 1, wherein the body comprises a transparent bulb or transparent tube.

3. The laser-sustained broadband light source of claim 2, wherein the body is formed from at least one of fused silica or sapphire.

4. The laser-sustained broadband light source of claim 1, wherein the one or more windows are formed from a material transparent to at least one of VUV light or infrared light.

5. The laser-sustained broadband light source of claim 4, wherein the one or more windows are formed from at least one of MgF₂, CaF₂, LiF, sapphire, or SBO.

6. The laser-sustained broadband light source of claim 1, further comprising:
one or more sleeves, wherein a respective sleeve hermetically seals a respective window and a respective extension portion.

7. The laser-sustained broadband light source of claim 6, wherein the one or more sleeves are formed from at least one of a metal, a glass, or a ceramic.

8. The laser-sustained broadband light source of claim 6, wherein a respective sleeve is bonded to a respective window via an interlayer material.

9. The laser-sustained broadband light source of claim 6, wherein a respective sleeve is directly bonded to a respective window.

10. The laser-sustained broadband light source of claim 6, wherein a respective sleeve is bonded to a respective window via one or more mechanical elements, wherein the one or more mechanical elements a mechanical seal and a retaining ring.

11. The laser-sustained broadband light source of claim 6, wherein a respective sleeve is bonded to a respective extension portion via one or more interlayers of material.

12. The laser-sustained broadband light source of claim 6, wherein a respective sleeve is directly bonded to a respective extension portion.

13. The laser-sustained broadband light source of claim 6, wherein a respective sleeve is bonded to a respective extension portion via a mechanical connection.

14. The laser-sustained broadband light source of claim 1, wherein the respective window is bonded to the respective extension portion via one or more interlayers of material.

15. The laser-sustained broadband light source of claim 1, wherein the respective window is directly bonded to the respective extension portion.

16. The laser-sustained broadband light source of claim 1, wherein the respective window and the respective extension portion are hermetically sealed via a compressive mechanical seal.

17. The laser-sustained broadband light source of claim 1, further comprising a fill port configured to introduce the pressurized gas into the sealed internal gas volume of the body of the gas containment structure.

18. The laser-sustained broadband light source of claim 17 wherein further comprising a valve connected to the fill port.

19. The laser-sustained broadband light source of claim 17, wherein the fill port is integrated into a sleeve.

20. The laser-sustained broadband light source of claim 17, wherein the fill port is formed within a window secured by a sleeve.

21. The laser-sustained broadband light source of claim 17, wherein the fill port is formed through a wall of the body of the gas containment structure.

22. The laser-sustained broadband light source of claim 1, further comprising one or more retroreflectors configured to redirect broadband light into the plasma.

23. The laser-sustained broadband light source of claim 22, wherein at least one retroreflector is disposed outside the gas containment structure to reflect broadband light back through a respective window.

24. The laser-sustained broadband light source of claim 1, further comprising a constriction hole formed in the body to regulate gas flow within the sealed internal gas volume.

25. The laser-sustained broadband light source of claim 1, further comprising a pair of electrodes disposed within the gas containment structure to assist in plasma ignition.

26. The laser-sustained broadband light source of claim 1, wherein the pressurized gas comprises at least one a single gas or a mixture of two or more gases.

27. The laser-sustained broadband light source of claim 26, wherein the pressurized gas comprises at least one of xenon, argon, or krypton.

28. The laser-sustained broadband light source of claim 1, wherein the pump laser source comprises one or more continuous-wave lasers.

29. The laser-sustained broadband light source of claim 1, further comprising:
a pulsed laser for generating an ignition beam for igniting the plasma.

30. The laser-sustained broadband light source of claim 29, wherein the ignition beam of the pulsed laser and the pump beam of the pump laser source at least partially share an optical path.

31. The laser-sustained broadband light source of claim 1, wherein the light collector element comprises a reflector assembly.

32. The laser-sustained broadband light source of claim 31, wherein the reflector assembly comprises at least one of an elliptical reflector or a spherical reflector.

33. A characterization system comprising:
a laser-sustained light source comprising:
a gas containment structure configured to contain a pressurized gas;
one or more pump laser sources configured to generate a pump beam;
wherein the gas containment structure comprises:
a body formed from a first optically transparent material transmissive to a pump laser beam;
one or more windows formed from a material transmissive to vacuum ultraviolet light;
one or more extension portions, wherein a respective extension portion connects the body of the gas containment structure with a respective window;
wherein the respective window is hermetically joined to the respective extension portion to define a sealed internal gas volume;
one or more optical elements configured to direct a pump laser beam from the pump source through the body of the gas containment structure into the sealed internal gas volume to sustain a plasma in the gas; and
a light collector element configured to collect broadband light emitted by the plasma through the one or more windows,
wherein the characterization system further comprises:
a set of illumination optics configured to direct broadband light from the laser-sustained light source to one or more samples;
a set of collection optics configured to collect light emanating from the one or more samples; and
a detector assembly.

34. A method of broadband light generation comprising:
providing a gas containment structure, the gas containment structure comprising:
a body formed from a first optically transparent material transmissive to a pump laser beam;
one or more windows formed from a material transmissive to vacuum ultraviolet light; and
one or more extension portions, each extension portion connecting the body to a respective window transmissive to vacuum ultraviolet light, wherein each window is hermetically joined to a corresponding extension portion to define a sealed internal gas volume;
introducing a pressurized gas into the sealed internal gas volume;
generating a pump beam with one or more pump laser sources;
directing the pump beam through the body into the sealed internal gas volume via one or more optical elements to ignite and sustain a plasma in the pressurized gas; and
collecting broadband light emitted by the plasma through the windows using a light collector element.
